(19) United States
(12) Patent Application Publication
(10) Pub. No.: US 2023/0178557 A1
(43) Pub. Date: Jun. 8, 2023

(54) SEMICONDUCTOR STRUCTURE OF LOGIC CELL WITH SMALL CELL DELAY

(71) Applicant: MEDIATEK INC., Hsinchu City (TW)

(72) Inventors: Ho-Chieh HSIEH, Hsinchu City (TW); Kin-Hooi DIA, Hsinchu City (TW); Hsing-I TSAI, Hsinchu City (TW)

(21) Appl. No.: 18/050,630

(22) Filed: Oct. 28, 2022

Related U.S. Application Data
(60) Provisional application No. 63/286,583, filed on Dec. 7, 2021.

(51) Int. Cl. H01L 27/118; H01L 27/02

(52) U.S. Cl. CPC H01L 27/11807; H01L 27/0207; H01L 2027/11829; H01L 2027/11881

(57) ABSTRACT

A semiconductor structure is provided. A logic cell includes a first transistor in a first active region, a second gate electrode and a third gate electrode on opposite sides of the first transistor, a second transistor in a second active region, and a first isolation structure and a second isolation structure on opposite edges of the second active region. The first transistor includes a first gate electrode extending in a first direction. The second and third gate electrodes extend in the first direction, and the first and second isolation structures extend in the first direction. The second transistor and the first transistor share the first gate electrode. The first isolation structure is aligned with the second gate structure in the first direction, and the second isolation structure is aligned with the third gate structure in the first direction.

### CROSS REFERENCE TO RELATED APPLICATIONS

This application claims priority of U.S. Provisional Application No. 63/286,583, filed on Dec. 7, 2021, the entirety of which is incorporated by reference herein.

### BACKGROUND OF THE INVENTION

### Field of the Invention

The invention relates to a logic cell, and more particularly to a high-speed logic cell.

### Description of the Related Art

Integrated circuits (ICs) have become increasingly important. Applications using ICs are used by millions of people. These applications include cell phones, smartphones, tablets, laptops, notebook computers, PDAs, wireless email terminals, MP3 audio and video players, portable wireless web browsers, and so on. Integrated circuits increasingly include powerful and efficient on-board data storage and logic circuitry for signal control and processing.

With the increasing down-scaling of integrated circuits, the integrated circuits have become more compact. For standard cells that are frequently used in integrated circuits, when the number of standard cells is increased, the chip area is increased. Therefore, a standard cell with a smaller area and better efficiency is desired.

### BRIEF SUMMARY OF THE INVENTION

Semiconductor structures are provided. An embodiment of a semiconductor structure is provided. The semiconductor structure includes a semiconductor substrate, a first well region with a first conductivity type over the semiconductor substrate, a second well region with a second conductivity type over the semiconductor substrate, and a logic cell. The first conductivity type is different from the second conductivity type. The logic cell includes at least one first transistor in a first active region over the first well region, a second gate electrode and a third gate electrode on opposite sides of the first transistor, at least one second transistor in a second active region over the second well region, and a first isolation structure and a second isolation structure on opposite edges of the second active region. The first transistor includes a first gate electrode extending in a first direction. The second and third gate electrodes extend in the first direction, and the first and second isolation structures extend in the first direction. The second transistor and the first transistor share the first gate electrode. The first isolation structure is aligned with the second gate structure in the first direction, and the second isolation structure is aligned with the third gate structure in the first direction.

Furthermore, an embodiment of a semiconductor structure is provided. The semiconductor structure includes a semiconductor substrate, a logic cell, a first power line, a second power line and a first additional power line. The logic cell includes at least one first transistor in a first active region over the semiconductor substrate, a second gate electrode and a third gate electrode on opposite sides of the first transistor and extending in a first direction, at least one second transistor in a second active region over the semiconductor substrate, and a fourth gate electrode and a fifth gate electrode on opposite sides of the second transistor and extending in the first direction. The first transistor includes a first gate electrode extending in the first direction. The second transistor and the first transistor share the first gate electrode. The first power line extends in a second direction, and the second direction is perpendicular to the first direction. The second power line extends in the second direction. The logic cell is surrounded by the first and second power lines, and the first power line is electrically separated from the second power line. The first additional power line extends in the second direction and over the first active region. The fourth gate structure is electrically separated from the second gate structure, and the fifth gate structure is electrically separated from the third gate structure. The second and third gate electrodes are electrically connected to the first power line through the first additional power line.

Moreover, an embodiment of a semiconductor structure is provided. The semiconductor structure includes a semiconductor substrate and a cell array. The cell array includes a first logic cell, a second logic cell, a third gate electrode, a fourth gate electrode, a fifth gate electrode, a first isolation structure, a second isolation structure and a third isolation structure. The first logic cell includes at least one first transistor in a first active region over the semiconductor substrate and at least one second transistor in a second active region over the semiconductor substrate. The first transistor includes a first gate electrode extending in a first direction. The second transistor and the first transistor share the first gate electrode. The second logic cell includes at least one third transistor in the first active region and at least one fourth transistor in a third active region over the semiconductor substrate. The third transistor includes a second gate electrode extending in the first direction. The third transistor and the fourth transistor share the second gate electrode. The third and fourth gate electrodes are disposed on opposite sides of the first transistor and extending in the first direction, and the fourth and fifth gate electrodes are disposed on opposite sides of the third transistor and extending in the first direction. The first and second isolation structures on opposite edges of the second active region, and the second and third isolation structures on opposite edges of the third active region. The second active region is separated from the third active region by the second isolation structure.

A detailed description is given in the following embodiments with reference to the accompanying drawings.

### BRIEF DESCRIPTION OF DRAWINGS

The invention can be more fully understood by reading the subsequent detailed description and examples with references made to the accompanying drawings, wherein:

FIG. 1 shows a simplified diagram illustrating a cell array of an IC according to some embodiments of the invention.

FIG. 2 shows a simplified diagram illustrating a logic cell according to some embodiments of the invention.

FIG. 3 shows a simplified diagram illustrating the logic cells of FIG. 2 arranged in a row of the cell array of FIG. 1 according to some embodiments of the invention.

FIG. 4A shows a cross-sectional view of the semiconductor structure of the row along line A-AA in FIG. 3 according to some embodiments of the invention.

FIG. 4B shows a cross-sectional view of the semiconductor structure of the row along line B-BB in FIG. 3 according to some embodiments of the invention.

FIG. 5 shows a simplified diagram illustrating a logic cell according to some embodiments of the invention.

FIG. 6 shows a simplified diagram illustrating the logic cells of FIG. 5 arranged in a row of the cell array of FIG. 1 according to some embodiments of the invention.

FIG. 7 shows a simplified diagram illustrating a logic cell according to some embodiments of the invention.

FIG. 8 shows a simplified diagram illustrating the logic cells of FIG. 7 arranged in a row of the cell array of FIG. 1 according to some embodiments of the invention.

FIG. 9 shows a simplified diagram illustrating the logic cells of FIG. 7 arranged in a row of the cell array of FIG. 1 according to some embodiments of the invention.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

Some variations of the embodiments are described. Throughout the various views and illustrative embodiments, like reference numbers are used to designate like elements. It should be understood that additional operations can be provided before, during, and/or after a disclosed method, and some of the operations described can be replaced or eliminated for other embodiments of the method.

Furthermore, spatially relative terms, such as “beneath,” “below,” “lower,” “above,” “upper” and the like, may be used herein for ease of description to describe one element or feature's relationship to another element(s) or feature(s) as illustrated in the figures.

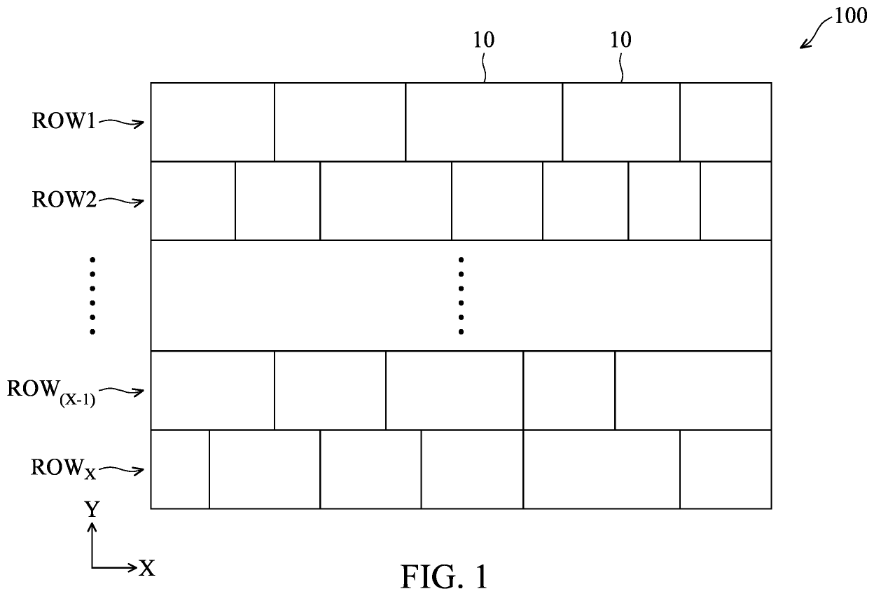

FIG. 1 shows a simplified diagram illustrating a cell array 100 of an IC according to some embodiments of the invention. The cell array 100 includes multiple logic cells 10 arranged in multiple rows ROW1 through ROWx. In some embodiments, the logic cells 10 are the standard cells (e.g., INV (inverter), AND, OR, NAND, NOR, Flip-Flop, SCAN, etc.), a combination thereof or specific logic functional cells. Furthermore, the logic functions of the logic cells 10 in the same row may be the same or different. Furthermore, each logic cell 10 includes a plurality of transistors. In some embodiments, the logic cells 10 corresponding to the same function or operation may have the same circuit configuration with different semiconductor structures and/or different layouts. In FIG. 1, the logic cells 10 in the same row have the same cell height (e.g., in the Y-direction) in the layout. Furthermore, the logic cells 10 may have the same or different cell widths (e.g., in X-direction) in the layout. It should be noted that the number and the configuration of the logic cells 10 are used as an example, and not to limit the invention.

In some embodiments, the transistors in the logic cells 10 are selected from a group consisting of planar transistors, fin field effect transistors (FinFETs), vertical gate all around (GAA), horizontal GAA, nano wire, nano sheet, or a combination thereof.

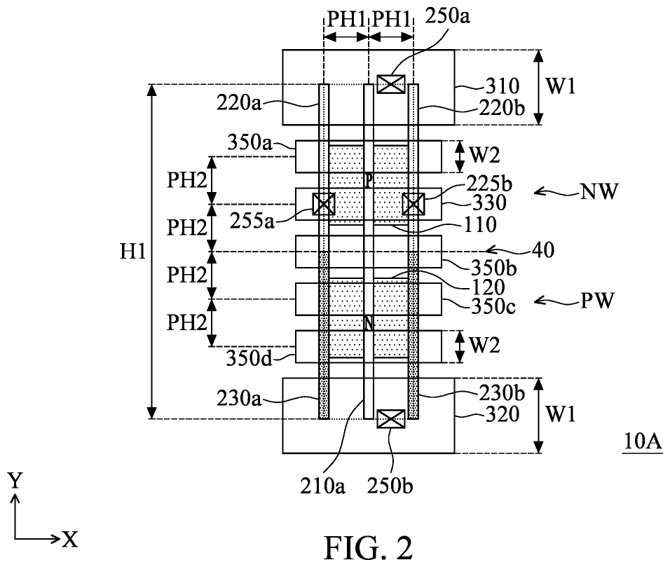

FIG. 2 shows a simplified diagram illustrating a logic cell 10A according to some embodiments of the invention. The logic cell 10A is capable of providing a specific logic function with small cell delay. The logic cell 10A is arranged between a power line 310 (e.g., VDD line, a first power line or a first power supply line) and a ground line 320 (e.g., VSS line, a second power line or a second power supply line), and has a cell height H1. Furthermore, the outer boundary of the logic cell 10A is illustrated using dashed lines. The power line 310 and the ground line 320 extending in the X-direction are main power supply lines for the logic cells in cell array 100. Furthermore, the logic cell 10A is surrounded by the power line 310 and the ground line 320.

The logic cell 10A includes a P-type transistor P over an N-type well region NW and an N-type transistor N over a P-type well region PW. In such embodiment, an interface between the N-type well region NW and the P-type well region PW is labeled as 40. The P-type transistor P and the N-type transistor N are configured to perform the specific logic function for the logic cell 10A, such as an inverter. It should be noted that the number of transistors in the logic cell 10A is used as an example, and not to limit the disclosure. The logic cell 10A may include more P-type transistors and more N-type transistors to perform a specific function.

In the logic cell 10A, a gate structure 210a extending in the Y-direction forms the P-type transistor P in the active region 110 of the N-type well region NW. Moreover, the gate structure 210a forms the N-type transistor N in the active region 120 of the P-type well region PW. The gate structures 220a and 220b extending in the Y-direction are arranged in the boundary of the logic cell 10A over the N-type well region NW. In some embodiments, the gate structures 210a, 220a and 220b have the same structure. In order to simplify, detail of the gate structures 210a, 220a and 220b, such as the gate dielectric, the gate electrode and so on, and corresponding source/drain regions, will be omitted.

The isolation structures 230a and 230b extending in the Y-direction are arranged in the boundary of the logic cell 10A over the P-type well region PW. In other words, the gate structures 220a and 220b are arranged on the opposite side of the P-type transistor P, and the isolation structures 230a and 230b are arranged on the opposite side of the N-type transistor N. It should be noted that the gate structures 220a and 220b and the isolation structures 230a and 230b are shorter than the gate structure 210a. In some embodiments, the gate structures 220a and 220b and the isolation structures 230a and 230b have the same length in the Y-direction.

In some embodiments, the isolation structures 230a and 230b are formed by performing a cut metal gate (CMG) process or a cut poly (CPO) process on the gate structures 220a and 220b that have the same length as the gate structure 210a. Next, the gate features of the gate structures 220a and 220b over the P-type well region are replaced with the dielectric-base material to form the isolation structures 230a and 230b.

In the logic cell 10A, the gate structures 210a, 220a and 220b are arranged with a fixed pitch PH1. For example, the gate structures 220a, 210a and 220b are arranged in sequence according to the pitch PH1.

The power line 310 and the ground line 320 are formed in the same metal layer, e.g., the lowest metal layer, and the power line 310 and the ground line 320 have the same width W1. The active regions 110 and 120 are arranged between the power line 310 and the ground line 320. In some embodiments, the cell height H1 is equal to a distance from a center of the power line 310 to a center of the ground line 320. Multiple signal lines 350a through 350d and an additional power line 330 extending in the X-direction are arranged between the power line 310 and the ground line 320 with a fixed pitch PH2. Furthermore, the signal lines 350a through 350d and the additional power line 330, the power line 310 and the ground line 320 are formed in the same metal layer. In some embodiments, the signal lines 350a through 350d and the additional power line 330 have the same width W2. It should be noted that the signal lines 350a through 350d and the additional power line 330 are narrower than the power line 310 and the ground line 320, i.e., the width W2 is less than the width W1 (W2<W1). It should be noted that the width W1 is less than the traditional power/ground line of the traditional logic cells that arrange tie-gate connection feature over the traditional power/ground line. Therefore, the cell height H1 is less than a cell height of the traditional logic cells.

The signal line 350b is formed over the interface 40 between the N-type well region NW and the P-type well region PW. The gate structure 210a is electrically connected to one of the signal lines 350a through 350d through the corresponding connection feature (not shown). Furthermore, the source/drain regions of the P-type transistor P and the N-type transistor N may connect to the corresponding signal lines, i.e., the signal lines 350a through 350d other than the signal line connected to the gate structure 210a.

The additional power line 330 is a metal line that may be a signal line dedicated for connecting the power line 310. The additional power line 330 is electrically connected to the gate structures 220a and 220b through the connection features 255a and 255b, respectively. Furthermore, the additional power line 330 is electrically connected to the power line 310 through an interconnect structure (not shown). In some embodiments, the connection feature 255a (i.e., tie-gate connection feature) and the gate structure 220a form a first tie-gate device, and the connection feature 255b and the gate structure 220b form a second tie-gate device. As described above, the first and second tie-gate devices are arranged in the boundary of the logic cell 10A. Furthermore, the N-type transistor N is surrounded by the first and second tie-gate devices. Compared with the traditional logic cells, no tie-gate connection feature is formed directly above the power line 310 and the ground line 320 in the logic cell 10A.

The connection feature 250a is configured to connect the source/drain region (not shown) of the P-type transistor P to the power line 310. The connection feature 250b is configured to connect the source/drain region (not shown) of the N-type transistor N to the ground line 320. In some embodiments, each of the connection features 250a and 250b is a contact for connecting the source/drain region of the transistor.

The isolation structure 230a and the gate structure 220a are disposed along the same line in the Y-direction, and the isolation structure 230b and the gate structure 220b are disposed along the same line in the Y-direction. In other words, the isolation structure 230a is aligned with the gate structure 220a, and the isolation structure 230b is aligned with the gate structure 220b in the Y-direction. In some embodiments, the isolation structure 230a is in contact with the gate structure 220a, and the isolation structure 230b is in contact with the gate structure 220b. In some embodiments, the isolation structure 230a is separated from the gate structure 220a by a dielectric material, and the isolation structure 230b is separated from the gate structure 220b by a dielectric material.

In the logic cell 10A, the active region 110 is formed by a continuous oxide diffusion region, and the active region 120 is formed by a diffusion break (DB) region. Therefore, the active region 120 corresponding to the N-type transistor N is separated from the active region corresponding to the N-type transistor of the adjacent logic cell by the isolation structures 230a and 230b. In some embodiments, the isolation structure 230a and 230b may be the DB structure. In some embodiment, the isolation structure 230a and 230b may be the shallow trench isolation (STI). In some embodiments, the isolation structure 230a and 230b may be the dielectric-base dummy gate.

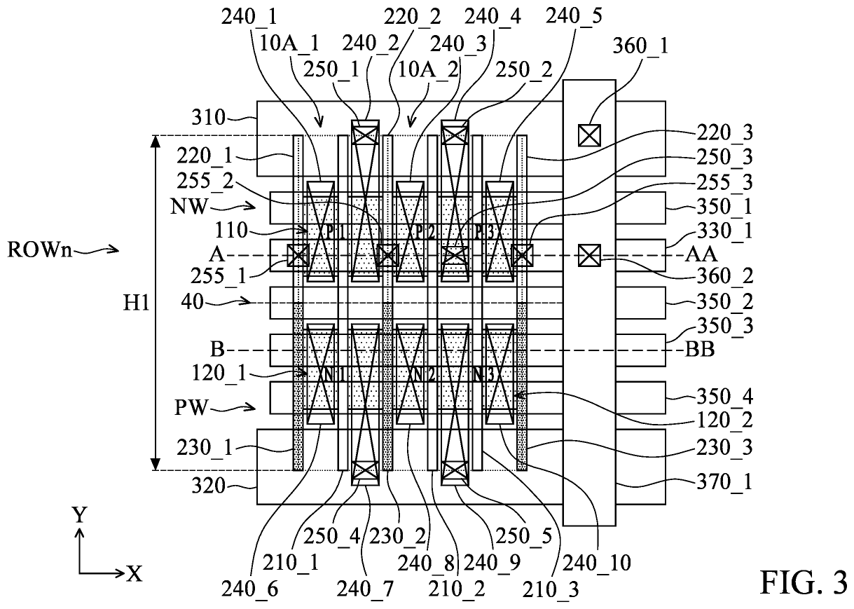

FIG. 3 shows a simplified diagram illustrating the logic cells 10A of FIG. 2 arranged in a row ROWn of the cell array 100 of FIG. 1 according to some embodiments of the invention. The logic cells 10A_1 and 10A_2 are arranged in the row ROWn and between the power line 310 and the ground line 320. Furthermore, the outer boundary of each of the logic cells 10A_1 and 10A_2 is illustrated using dashed lines. The logic cells 10A_1 and 10A_2 have the cell height H1 in FIG. 3.

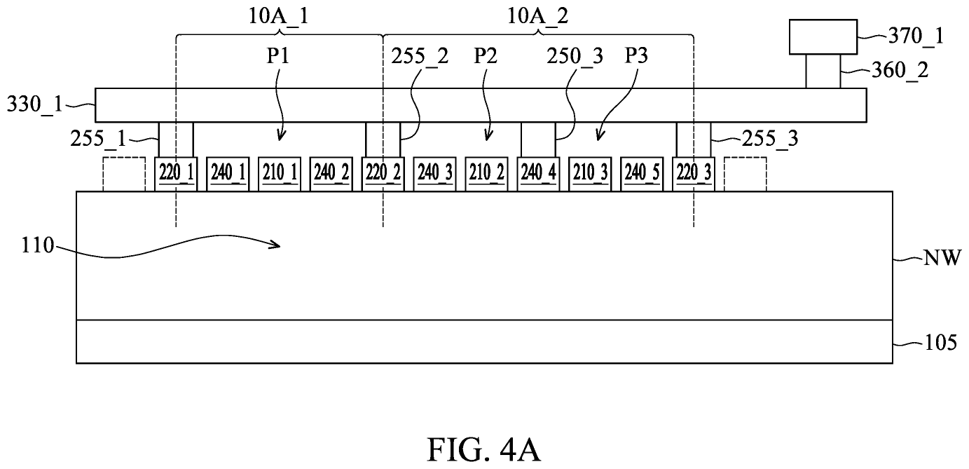

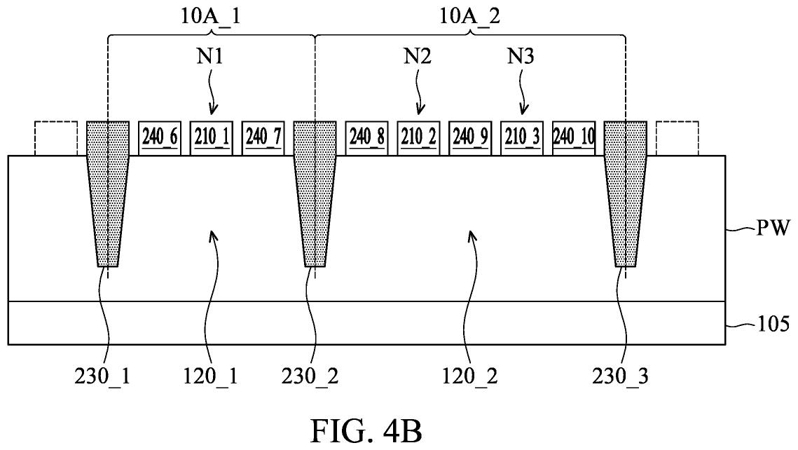

FIG. 4A shows a cross-sectional view of the semiconductor structure of the row ROWn along line A-AA in FIG. 3 according to some embodiments of the invention. FIG. 4B shows a cross-sectional view of the semiconductor structure of the row ROWn along line B-BB in FIG. 3 according to some embodiments of the invention.

Referring to FIG. 3 and FIGS. 4A and 4B together, the N-type well region NW and the P-type well region PW are formed over a semiconductor substrate 105. In some embodiments, the semiconductor substrate 105 is a Si substrate. In some embodiments, the material of the semiconductor substrate 105 is selected from a group consisting of bulk-Si, SiP, SiGe, SiC, SiPC, Ge, SOI-Si, SOI-SiGe, III-VI material, or a combination thereof.

In the logic cell 10A_1, the gate structure 210_1 extending in the Y-direction forms the P-type transistor P1 in the active region 110 of the N-type well region NW and the N-type transistor N1 in the active region 120_1 of the P-type well region PW. In the logic cell 10A_2, the gate structures 210_2 and 210_3 extending in the Y-direction respectively form the P-type transistors P2 and P3 in the active region 110 of the N-type well region NW, and respectively form the N-type transistors N2 and N3 in the active region 120_2 of the P-type well region PW. In order to simplify, the source/drain regions of the P-type transistors P1 through P3 and the N-type transistors N1 through N3 are omitted.

The gate structures 220_1 and 220_2 extending in the Y-direction are arranged in the boundary of the logic cell 10A_1 over the N-type well region NW, and the gate structures 220_2 and 220_3 extending in the Y-direction are arranged in the boundary of the logic cell 10A_2 over the N-type well region NW. The gate structure 220_2 is shared by the logic cells 10A_1 and 10A_2. Furthermore, the active region 110 is a continuous oxide diffusion region that extends in the X-direction.

The isolation structures 230_1 and 230_2 extending in the Y-direction are arranged in the boundary of the logic cell 10A_1 over the P-type well region PW, and the isolation structures 230_2 and 230_3 extending in the Y-direction are arranged in the boundary of the logic cell 10A_2 over the P-type well region PW. The isolation structure 230_2 is shared by the logic cells 10A_1 and 10A_2.

The P-type transistor P1 and the N-type transistor N1 are configured to perform a first logic function for the logic cell 10A_1. The P-type transistors P2 and P3 and the N-type transistors N2 and N3 are configured to perform a second logic function for the logic cell 10A_2. In some embodiments, the first and second logic functions are different. For example, the logic cell 10A_1 is an inverter (NOT gate), and the logic cell 10A_2 is a NAND gate or an NOR gate. In some embodiments, the first and second logic functions are the same. For example, the logic cells 10A_1 and 10A_2 are inverters with different driving strengths.

The P-type transistors P1 through P3 are formed in the same active region 110. For example, the P-type transistors P1 through P3 share the same fin structure or GAA structure. The N-type transistor N1 is formed in the active region 120_1, and the N-type transistors N2 and N3 are formed in the active region 120_2. The isolation structures 230_1 and 230_2 are arranged on the opposite edges of the active region 120_1, and the isolation structures 230_2 and 230_3 are arranged on the opposite edges of the active region 120_2. Furthermore, the active region 120_1 is separated from the active region 120_2 by the isolation structure 230_2.

In the logic cells 10A_1 and 10A_2, the gate structures 220_1, 210_1, 220_2, 210_2, 210_3 and 220_3 are arranged with a fixed pitch (e.g., the pitch PH1 of FIG. 2) in sequence. In the Y-direction, the isolation structure 230_1 is aligned with the gate structure 220_1, the isolation structure 230_2 is aligned with the gate structure 220_2, and the isolation structure 230_3 is aligned with the gate structure 220_3. In some embodiments, the isolation structures 230_1 through 230_3 are in contact with the gate structures 220_1 through 220_3, respectively. In some embodiments, the isolation structures 230_1 through 230_3 are separated from the gate structures 220_1 through 220_3 by a dielectric material.

In some embodiments, the gate structures 210_1 through 210_3 have the same length (e.g., the cell height H1) in the Y-direction. In some embodiments, the gate structures 220_1 through 220_3 only extends above the N-type well region NW, and does not extend above the P-type well region PW. Similarly, the isolation structures 230_1 through 230_3 only extends above the P-type well region PW, and does not extend above the N-type well region NW. Therefore, the gate structures 220_1 through 220_3 and the isolation structures 230_1 through 230_3 are shorter than the gate structures 210_1 through 210_3. Furthermore, the gate structures 220_1 through 220_3 have the same length in the Y-direction, and the isolation structures 230_1 through 230_3 have the same length in the Y-direction. In some embodiments, the gate structures 210_1 through 210_3, the gate structures 220_1 through 220_3 and the isolation structures 230_1 through 230_3 have the same width in the X-direction. Moreover, the gate structures 210_1 through 210_3 and the gate structures 220_1 through 220_3 are formed under and partially covered by the power line 310. The gate structures 210_1 through 210_3 and the isolation structures 230_1 through 230_3 are formed under and partially covered by the ground line 320. The power line 310 and the ground line 320 are main power supply lines for the logic cells 10A_1 and 10A_2, and extend in the X-direction across the logic cells 10A_1 and 10A_2.

Moreover, the connection features 240_1 through 240_5 extending in the Y-direction are positioned over the active region 110. The connection features 240_1 through 240_5 are formed in the same layer over the active region 110. In some embodiments, each of the connection features 240_1 through 240_5 is a contact for connecting the source/drain region of the transistor over the N-type well region NW. The connection feature 250_1 is formed over the connection feature 240_2, and the connection features 250_2 and 250_3 are formed over the connection feature 240_4. In some embodiments, each of the connection features 250_1 through 250_3 is a via for connecting the corresponding contact. Moreover, the connection features 250_1 through 250_3 are formed over the N-type well region NW.

The connection features 240_6 and 240_7 extending in the Y-direction are positioned over the active region 120_1, and the connection features 240_8 through and 240_10 extending in the Y-direction are positioned over the active region 120_2. The connection features 240_6 through 240_10 and the connection features 240_1 through 240_5 are formed in the same layer. In some embodiments, each of the connection features 240_6 through 240_10 is a contact for connecting the source/drain region of the transistor over the P-type well region PW. The connection features 250_4 and 250_5 are formed over the connection features 240_7 and 240_9, respectively. In some embodiments, each of the connection features 250_4 through 250_5 is a via for connecting the corresponding contact. Moreover, the connection features 250_4 and 250_5 are formed over the P-type well region PW.

The signal lines 350_1 through 350_4 and the additional power line 330_1 extending in the X-direction are arranged between the power line 310 and the ground line 320 according to a fixed pitch (e.g., the pitch PH2 of FIG. 2). As described above, the signal lines 350_1 through 350_4 and the additional power line 330_1 are narrower than the power line 310 and the ground line 320.

The additional power line 330_1 is a metal line that may be a signal line dedicated for connecting the power line 310. The additional power line 330_1 extends over the active region 110 and is electrically connected to the gate structures 220_1 through 220_3 through the connection features 255_1 through 255_3, respectively. Furthermore, the additional power line 330_1 is electrically connected to the power line 310 through the connection feature 360_2, the metal line 370_1 and the connection feature 360_1 in sequence. The metal line 370_1 extending in the Y-direction is formed in a metal layer over the additional power line 330_1. Simultaneously, the additional power line 330_1 is further electrically connected to the power line 310 through the connection feature 250_3, the connection feature 240_4 and the connection feature 250_2 in sequence. In some embodiments, more interconnect structures are used to connect the additional power line 330_1 to the power line 310.

In some embodiments, the materials of the connection features 240_1 through 240_10, the connection features 250_1 through 250_5, and the connection features 255_1 through 255_3 are selected from a group consisting of Ti, TiN, TaN, Co, Ru, Pt, Ni, W, Al, Cu, or a combination thereof. In some embodiments, the connection features 240_1 through 240_10, the connection features 250_1 through 250_5, and the connection features 255_1 through 255_3 are formed by the same material. In some embodiments, the connection features the connection features 240_1 through 240_10, the connection features 250_1 through 250_5, and the connection features 255_1 through 255_3 are formed by different materials.

In the row ROWn of FIG. 3, the additional power line 330_1 is capable of providing inbound power for the P-type transistors of the logic cells (e.g., the logic cells 10A_1 and 10A_2). Moreover, by using the additional power line 330_1 to tie the gate electrodes 220_1 through 220_3, the IR drop is decreased for the power delivery network (PDN) or power grid corresponding to the power line 310. Furthermore, the P-type transistors of the logic cells (e.g., the logic cells 10A_1 and 10A_2) are formed in the continuous active region 110, thereby avoiding the diffusion break stress that will degrade the saturation drain current (Idsat) of the P-type transistors, especially the P-type transistor with SiGe channel. Furthermore, when the diffusion break stress is mitigated, the threshold voltage (i.e., Vt) of the transistor is decreased.

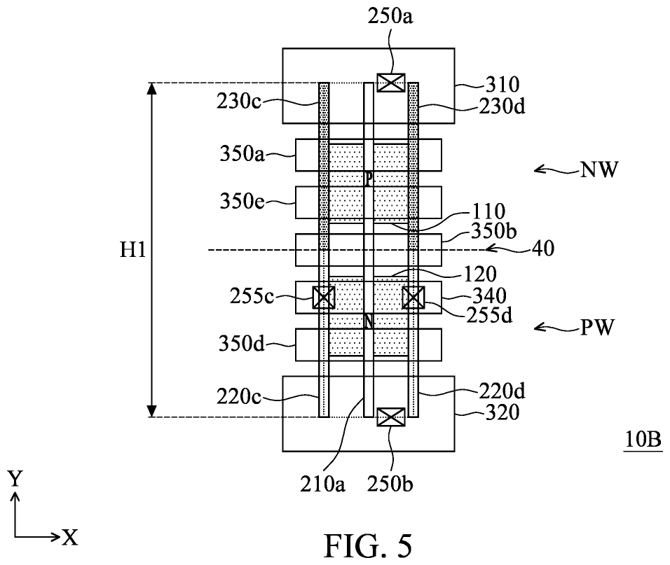

FIG. 5 shows a simplified diagram illustrating a logic cell 10B according to some embodiments of the invention. The outer boundary of the logic cell 10B is illustrated using dashed lines. The logic cell 10B is capable of providing a specific logic function similar to that of the logic cell 10A of FIG. 2. The semiconductor structure of the logic cell 10B is similar to the semiconductor structure of the logic cell 10A of FIG. 2, and the difference between the logic cells 10A and 10B is that the gate structures 220a and 220b of the logic cell 10A are replaced with the isolation structures 230c and 230d in the logic cell 10B, respectively. Moreover, the isolation structures 230a and 230b of the logic cell 10A are replaced with the gate structures 220c and 220d in the logic cell 10B, respectively. In order to simplify the description, the connection features for connecting the source/drain regions of the transistors are omitted. It should be noted that the number of transistors in the logic cell 10B is used as an example, and not to limit the disclosure. The logic cell 10B may include more P-type transistors and more N-type transistors to perform a specific function.

The gate structures 220c and 220d extending in the Y-direction are arranged in the boundary of the logic cell 10B over the P-type well region PW. The isolation structures 230c and 230d extending in the Y-direction are arranged in the boundary of the logic cell 10B over the N-type well region NW. In other words, the isolation structures 230c and 230d are arranged on the opposite sides of the P-type transistor P, and the gate structures 220c and 220d are arranged on the opposite side of the N-type transistor N. It should be noted that the gate structures 220c and 220d and the isolation structures 230c and 230d are shorter than the gate structure 210a. In some embodiments, the gate structures 220c and 220d and the isolation structures 230c and 230d have the same length in the Y-direction.

The difference between the logic cell 10A of FIG. 2 and the logic cell 10B of FIG. 5 is that the additional power line 310 of the logic cell 10A is replaced with a signal line 350e in the logic cell 10B, and the signal line 350c of the logic cell 10A is replaced with an additional ground line 340 in the logic cell 10B. As described above, the signal lines 350a, 350b, 350d and 350e and the additional ground line 340 are narrower than the power line 310 and the ground line 320.

The additional ground line 340 is a metal line that may be a signal line dedicated for connecting the ground line 320. The additional ground line 340 is electrically connected to the gate structures 220c and 220d through the connection features 255c and 255d, respectively. Furthermore, the additional ground line 340 is electrically connected to the ground line 320 through an interconnect structure (not shown). In some embodiments, the connection feature 255c and the gate structure 220c form a third tie-gate device, and the connection feature 255d and the gate structure 220d form a fourth tie-gate device. As described above, the third and fourth tie-gate devices are arranged in the boundary of the logic cell 10B. Furthermore, the N-type transistor N is surrounded by the third and fourth tie-gate devices.

The isolation structure 230c and the gate structure 220c are disposed along the same line in the Y-direction, and the isolation structure 230d and the gate structure 220d are disposed along the same line in the Y-direction. In other words, the isolation structure 230c is aligned with the gate structure 220c and the isolation structure 230d is aligned with the gate structure 220d in the Y-direction. In some embodiments, the isolation structure 230c is in contact with the gate structure 220c, and the isolation structure 230d is in contact with the gate structure 220d. In some embodiments, the isolation structure 230c is separated from the gate structure 220c by a dielectric material, and the isolation structure 230d is separated from the gate structure 220d by a dielectric material.

In the logic cell 10B, the active region 120 is formed by a continuous oxide diffusion region, and the active region 110 is formed by a DB region. Therefore, the active region 110 corresponding to the P-type transistor P is separated from the active region corresponding to the P-type transistor of the adjacent logic cell by the isolation structures 230c and 230d. In some embodiments, the isolation structure 230c and 230d may be the DB structure. In some embodiment, the isolation structure 230c and 230d may be the STI. In some embodiments, the isolation structure 230c and 230d may be the dielectric-base dummy gate.

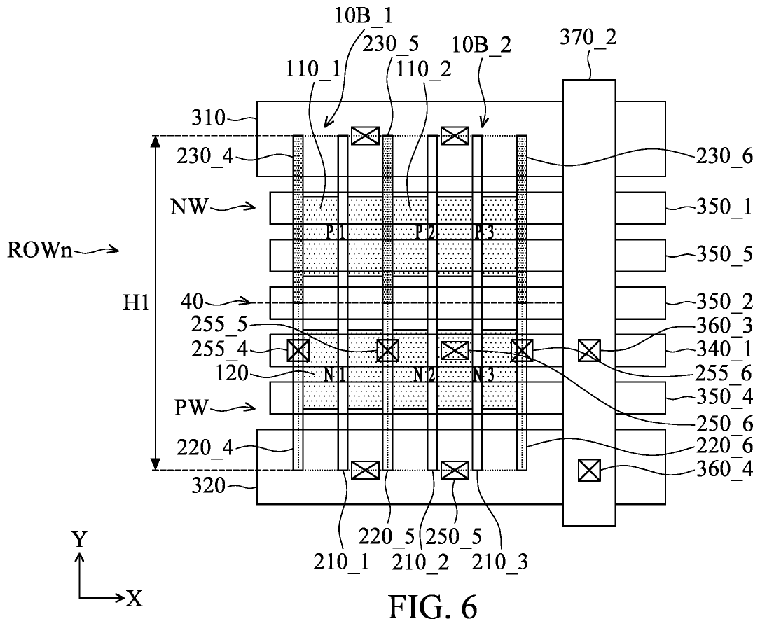

FIG. 6 shows a simplified diagram illustrating the logic cells 10B of FIG. 5 arranged in a row ROWn of the cell array 100 of FIG. 1 according to some embodiments of the invention. The logic cells 10B_1 and 10B_2 are arranged in the row ROWn and between the power line 310 and the ground line 320. Furthermore, the outer boundary of each of the logic cells 10B_1 and 10B_2 is illustrated using dashed lines. The logic cells 10B_1 and 10B_2 have the cell height H1 in FIG. 6.

In the logic cell 10B_1, the gate structure 210_1 extending in the Y-direction forms the P-type transistor P1 in the active region 110_1 of the N-type well region NW and the N-type transistor N1 in the active region 120 of the P-type well region PW. In the logic cell 10B_2, the gate structures 210_2 and 210_3 extending in the Y-direction forms the P-type transistors P2 and P3 in the active region 110_2 of the N-type well region NW and the N-type transistors N2 and N3 in the active region 120 of the P-type well region PW. In order to simplify, the source/drain regions of the P-type transistors P1 through P3 and the N-type transistors N1 through N3 are omitted.

The gate structures 220_4 and 220_5 extending in the Y-direction are arranged in the boundary of the logic cell 10B_1 over the P-type well region PW, and the gate structures 220_5 and 220_6 extending in the Y-direction are arranged in the boundary of the logic cell 10B_2 over the P-type well region PW. The gate structure 220_5 is shared by the logic cells 10B_1 and 10B_2. Furthermore, the active region 120 is a continuous oxide diffusion region that extends in the X-direction.

The isolation structures 230_4 and 230_5 extending in the Y-direction are arranged in the boundary of the logic cell 10B_1 over the N-type well region NW, and the isolation structures 230_5 and 230_6 extending in the Y-direction are arranged in the boundary of the logic cell 10B_2 over the N-type well region NW. The isolation structure 230_5 is shared by the logic cells 10B_1 and 10B_2.

In FIG. 6, the N-type transistors N1 through N3 are formed in the same active region 120. For example, the N-type transistors N1 through N3 share the same fin structure or GAA structure. The P-type transistor P1 is formed in the active region 110_1, and the P-type transistors P2 and P3 are formed in the active region 110_2. The isolation structures 230_4 and 230_5 are arranged on the opposite edges of the active region 110_1, and the isolation structures 230_5 and 230_6 are arranged on the opposite edges of the active region 110_2. In other words, the active region 110_1 is separated from the active region 110_2 by the isolation structure 230_5.

In the logic cells 10B_1 and 10B_2, the gate structures 210_1 through 210_3 and the gate structures 220_4 through 220_6 are arranged according to a fixed pitch, e.g., the pitch PH1 of FIG. 2. In the Y-direction, the isolation structure 230_4 is aligned with the gate structure 220_4, the isolation structure 230_5 is aligned with the gate structure 220_5, and the isolation structure 230_6 is aligned with the gate structure 220_6. In some embodiments, the isolation structures 230_4 through 230_6 are in contact with the gate structures 220_4 through 220_6, respectively. In some embodiments, the isolation structures 230_4 through 230_6 are separated from the gate structures 220_4 through 220_6 by a dielectric material.

In FIG. 6, the gate structures 220_4 through 220_6 only extends above the P-type well region PW, and does not extend above the N-type well region NW. Similarly, the isolation structures 230_4 through 230_6 only extends above the N-type well region NW, and does not extend above the P-type well region PW. Therefore, the gate structures 220_4 through 220_6 and the isolation structures 230_4 through 230_6 are shorter than the gate structures 210_1 through 210_3. Furthermore, the gate structures 220_4 through 220_6 have the same length in the Y-direction, and the isolation structures 230_4 through 230_6 have the same length in the Y-direction. Moreover, the gate structures 210_1 through 210_3, the gate structures 220_4 through 220_6 and the isolation structures 230_4 through 230_6 have the same width in the X-direction. Moreover, the gate structures 210_1 through 210_3 and the gate structures 220_4 through 220_6 are formed under and partially covered by the ground line 320. The gate structures 210_1 through 210_3 and the isolation structures 230_4 through 230_6 are formed under and partially covered by the power line 310.

The signal lines 350_1, 350_2, 350_4 and 350_5 and the additional ground line 340_1 extending in the X-direction are arranged between the power line 310 and the ground line 320 according to a fixed pitch (e.g., the pitch PH2 of FIG. 2). As described above, the signal lines 350_1, 350_2, 350_4 and 350_5 and the additional ground line 340_1 are narrower than the power line 310 and the ground line 320.

The additional ground line 340_1 is a metal line that may be a signal line dedicated for connecting the ground line 320. The additional ground line 340_1 is electrically connected to the gate structures 220_4 through 220_6 through the connection features 255_4 through 255_6, respectively. Furthermore, the additional ground line 340_1 is electrically connected to the ground line 320 through the connection feature 360_3, the metal line 370_2 and the connection feature 360_4 in sequence. The metal line 370_2 extending in the Y-direction is formed in a metal layer over the additional ground line 340_1. Simultaneously, the additional ground line 340_1 is further electrically connected to the ground line 320 through the connection feature 250_6, a connection feature (not shown) corresponding to the command drain/source region of the N-type transistors N2 and N3 and the connection feature 250_5 in sequence. In some embodiments, more interconnect structures are used to connect the additional ground line 340_1 to the ground line 320.

In the row ROWn of FIG. 6, the additional ground line 340_1 is capable of providing inbound ground for the N-type transistors of the logic cells (e.g., the logic cells 10B_1 and 10B_2). Moreover, by using the additional ground line 340_1 to tie the gate electrodes 220_4 through 220_6, the IR drop is decreased for the PDN or power grid corresponding to the ground line 320. Furthermore, the N-type transistors of the logic cells (e.g., the logic cells 10B_1 and 10B_2) are formed in the continuous active region 120, thereby avoiding the diffusion break stress that will degrade the saturation drain current (Idsat) of the N-type transistors. Furthermore, when the diffusion break stress is mitigated, the threshold voltage (i.e., Vt) of the transistor is decreased.

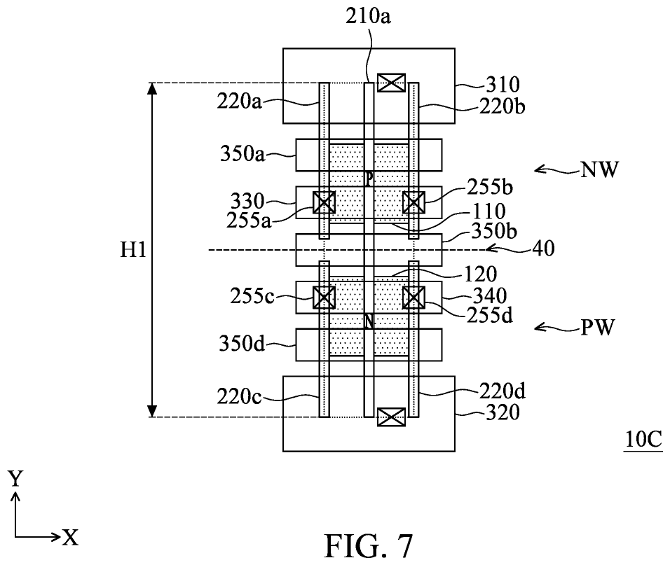

FIG. 7 shows a simplified diagram illustrating a logic cell 10C according to some embodiments of the invention. The outer boundary of the logic cell 10C is illustrated using dashed lines. The logic cell 10C is capable of providing a specific logic function similar to that of the logic cell 10A of FIG. 2. The semiconductor structure of the logic cell 10C is similar to the semiconductor structure of the logic cell 10A of FIG. 2, and the difference between the logic cells 10A and 10C is that the isolation structures 230a and 230b of the logic cell 10A are replaced with the gate structures 220c and 220d in the logic cell 10C, respectively. In other words, no isolation structure is formed in the logic cell 10C. In order to simplify the description, the connection features for connecting the source/drain regions of the transistors are omitted. It should be noted that the number of transistors in the logic cell 10C is used as an example, and not to limit the disclosure. The logic cell 10C may include more P-type transistors and more N-type transistors to perform a specific function.

In the logic cell 10C, the active regions 110 and 120 are formed by respective continuous oxide diffusion regions. In other words, no DB region is formed in the logic cell 10C. The gate structures 220c and 220d extending in the Y-direction are arranged in the boundary of the logic cell 10C over the P-type well region PW. The gate structures 220a and 220b extending in the Y-direction are arranged in the boundary of the logic cell 10C over the N-type well region NW. In other words, the gate structures 220a and 220b are arranged on the opposite side of the P-type transistor P, and the gate structures 220c and 220d are arranged on the opposite side of the N-type transistor N.

It should be noted that the gate structures 220a and 220b and the gate structures 220c and 220d are shorter than half of the gate structure 210a (e.g., half of the cell height H1). Therefore, the gate structures 220a and 220b do not contact the gate structures 220c and 220d, i.e., the gate structure 220a is separated from the gate structure 220c by a dielectric material, and the gate structure 220b is separated from the gate structure 220d by a dielectric material. In other words, the gate structures 220a and 220b and the gate structures 220c and 220d do not cross the interface 40 between the N-type well region NW and the P-type well region PW. Furthermore, the gate structure 220c is electrically separated from the gate structure 220a, and the gate structure 220d is electrically separated from the gate structure 220b.

The difference between the logic cell 10A of FIG. 2 and the logic cell 10C of FIG. 7 is that the signal line 350c of the logic cell 10A is replaced with the additional ground line 340 in the logic cell 10C. As described above, the additional ground line 340 is a metal line that may be a signal line dedicated for connecting the ground line 320, and the additional ground line 330 is a metal line that may be a signal line dedicated for connecting the power line 310. Furthermore, the additional ground line 340 and the additional power line 330 are electrically connected to the ground line 320 and the power line 310 through the respective interconnect structures.

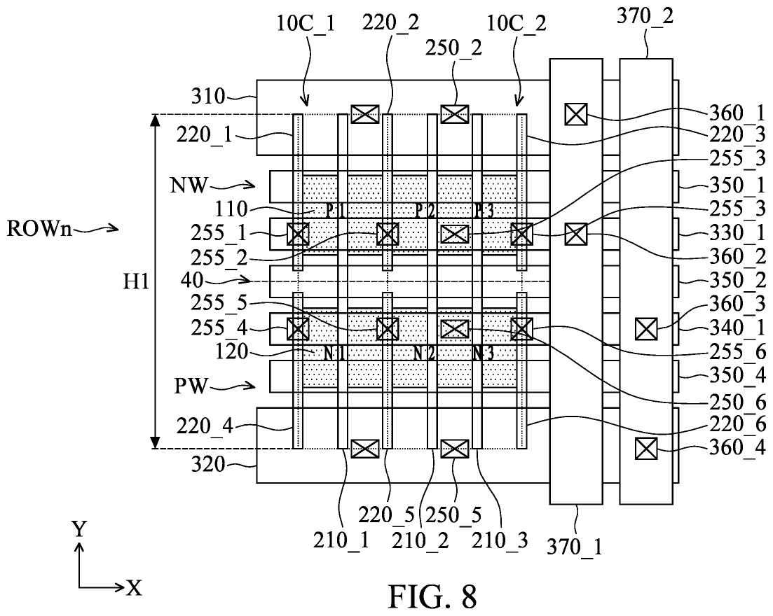

FIG. 8 shows a simplified diagram illustrating the logic cells 10C of FIG. 7 arranged in a row ROWn of the cell array 100 of FIG. 1 according to some embodiments of the invention. The logic cells 10C_1 and 10C_2 are arranged in the row and between the power line 310 and the ground line 320. Furthermore, the outer boundary of each of the logic cells 10C_1 and 10C_2 is illustrated using dashed lines. The logic cells 10C_1 and 10C_2 have the cell height H1 in FIG. 8.

In the logic cell 10C_1, the gate structure 210_1 extending in the Y-direction forms the P-type transistor P1 in the active region 110 of the N-type well region NW and the N-type transistor N1 in the active region 120 of the P-type well region PW. In the logic cell 10C_2, the gate structures 210_2 and 210_3 extending in the Y-direction forms the P-type transistors P2 and P3 in the active region 110 of the N-type well region NW and the N-type transistors N2 and N3 in the active region 120 of the P-type well region PW. In order to simplify, the source/drain regions of the P-type transistors P1 through P3 and the N-type transistors N1 through N3 are omitted.

The gate structures 220_1 and 220_2 extending in the Y-direction are arranged in the boundary of the logic cell 10C_1 over the N-type well region NW, and the gate structures 220_2 and 220_3 extending in the Y-direction are arranged in the boundary of the logic cell 10C_2 over the N-type well region NW. The gate structure 220_2 is shared by the logic cells 10C_1 and 10C_2. Furthermore, the active region 110 is a continuous oxide diffusion region that extends in the X-direction.

The gate structures 220_4 and 220_5 extending in the Y-direction are arranged in the boundary of the logic cell 10C_1 over the P-type well region PW, and the gate structures 220_5 and 220_6 extending in the Y-direction are arranged in the boundary of the logic cell 10C_2 over the P-type well region PW. The gate structure 220_5 is shared by the logic cells 10C_1 and 10C_2. Furthermore, the active region 120 is a continuous oxide diffusion region that extends in the X-direction. In other words, the N-type transistors N1 through N3 are formed over the same active region 120, and the P-type transistors P1 through P3 are formed over the same active region 110.

In FIG. 8, the gate structures 220_4 through 220_6 only extends above the P-type well region PW, and does not extend above the N-type well region NW. Similarly, the gate structures 220_1 through 220_3 only extends above the N-type well region NW, and does not extend above the P-type well region PW. In some embodiments, the gate structures 220_1 through 220_6 have the same length in the Y-direction. Moreover, the gate structures 210_1 through 210_3 and the gate structures 220_1 through 220_6 have the same width in the X-direction. Moreover, the gate structures 210_1 through 210_3 and the gate structures 220_4 through 220_6 are formed under and partially covered by the ground line 320. The gate structures 210_1 through 210_3 and the gate structures 220_1 through 220_3 are formed under and partially covered by the power line 310. Moreover, the gate structures 220_1 through 220_3 are electrically separated from the gate structures 220_4 through 220_6 by a dielectric material.

The signal lines 350_1, 350_2 and 350_4, the additional ground line 340_1, and the additional power line 330_1 extending in the X-direction are arranged between the power line 310 and the ground line 320 according to a fixed pitch (e.g., the pitch PH2 of FIG. 2). As described above, the signal lines 350_1, 350_2 and 350_4, the additional ground line 340_1, and the additional power line 330_1 are narrower than the power line 310 and the ground line 320.

The additional power line 330_1 is a metal line that may be a signal line dedicated for connecting the power line 310. The additional power line 330_1 is electrically connected to the gate structures 220_1 through 220_3 through the connection features 255_1 through 255_3, respectively. Furthermore, the additional power line 330_1 is electrically connected to the power line 310 through the connection feature 360_2, the metal line 370_1 and the connection feature 360_1 in sequence. Simultaneously, the additional power line 330_1 is further electrically connected to the power line 310 through the connection feature 250_3, a connection feature (e.g., the connection feature 240_4 of FIG. 3) corresponding to the command drain/source region of the P-type transistors P2 and P3, and the connection feature 250_2 in sequence. In some embodiments, more interconnect structures are used to connect the additional power line 330_1 to the power line 310.

The additional ground line 340_1 is a metal line that may be a signal line dedicated for connecting the ground line 320. The additional ground line 340_1 is electrically connected to the gate structures 220_4 through 220_6 through the connection features 255_4 through 255_6, respectively. Furthermore, the additional ground line 340_1 is electrically connected to the ground line 320 through the connection feature 360_3, the metal line 370_2 and the connection feature 360_4 in sequence. Simultaneously, the additional ground line 340_1 is further electrically connected to the ground line 320 through the connection feature 250_6, a connection feature (not shown) corresponding to the command drain/source region of the N-type transistors N2 and N3, and the connection feature 250_5 in sequence. In some embodiments, more interconnect structures are used to connect the additional ground line 340_1 to the ground line 320.

In FIG. 8, the additional power line 330_1 is arranged away from the power line 310, and.is surrounded by the signal lines 350_1 and 350_2. Moreover, the additional ground line 340_1 is arranged away from the ground line 320, and.is surrounded by the signal lines 350_4 and 350_2. Furthermore, the additional power line 330_1 is mirrored to the additional ground line 340_1 along the interface 40 between the N-type well region NW and the P-type well region PW, i.e., the configurations of the additional power line 330_1 and the additional ground line 340_1 are symmetrical in the layout.

In the row ROWn of FIG. 8, the additional ground line 340_1 is capable of providing inbound ground for the N-type transistors of the logic cells (e.g., the logic cells 10C_1 and 10C_2), and the additional power line 330_1 is capable of providing inbound power for the P-type transistors of the logic cells (e.g., the logic cells 10C_1 and 10C_2). Furthermore, all P-type transistors of the logic cells (e.g., the logic cells 10C_1 and 10C_2) are formed in the continuous active region 110 and all N-type transistors of the logic cells are formed in the continuous active region 120, thereby avoiding the diffusion break stress that will degrade the saturation drain current of the transistors.

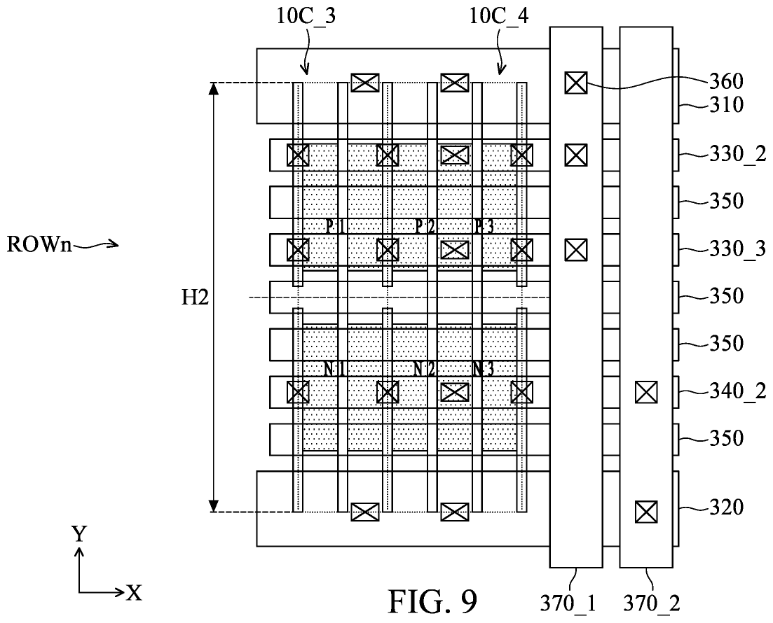

FIG. 9 shows a simplified diagram illustrating the logic cells 10C of FIG. 7 arranged in a row ROWn of the cell array 100 of FIG. 1 according to some embodiments of the invention. In FIG. 9, the logic cells 10C_3 and 10C_4 are arranged in the row ROWn and between the power line 310 and the ground line 320. Furthermore, the outer boundary of each of the logic cells 10C_3 and 10C_4 is illustrated using dashed lines. The logic cells 10C_3 and 10C_4 have the same cell height H2 that is greater than height H1 of FIG. 8. Therefore, more metal lines can be arranged between the power line 310 and the ground line 320. As described above, the metal lines may be the signal lines, the additional power lines, the additional power lines or the combination thereof.

Compared with the row ROWn in FIG. 8, more additional power lines (e.g., the additional power lines 330_2 and 330_3) and/or more additional power lines (not shown) can be arranged in the row of FIG. 9. Furthermore, the additional power line 330_2 is arranged close to the power line 310, and the additional power line 330_3 is arranged away from the power line 310. In such embodiment, the additional power line 330_2 is separated from the additional power line 330_3 by the signal line 350. In some embodiments, the additional power lines 330_2 and 330_3 are adjacent. The additional power line 330_2 is separated from the additional power line 330_3 by the signal line 350. Moreover, the configurations of the additional power lines 330_2 and 330_3 and the additional ground line 340_2 are asymmetrical in the layout. Therefore, the arrangement of the additional power lines and the additional ground lines is flexible.

In the embodiments, the semiconductor structures of logic cells capable of reducing delay time are provided. According to the embodiments, the logic cells 10A of FIG. 2, the logic cells 10B of FIG. 5 and the logic cells 10C of FIG. 7 can be arranged in respective cell arrays, respective rows of a cell array or the same row of a cell array. Furthermore, by inserting the additional power/ground lines and removing the diffusion edge, the threshold voltages of transistors in the logic cells are decreased, thereby increasing operation speed, and decreasing operating voltage and IR drop for the logic cells.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A semiconductor structure, comprising:
a semiconductor substrate;
a first well region with a first conductivity type over the semiconductor substrate;
a second well region with a second conductivity type over the semiconductor substrate, wherein the first conductivity type is different from the second conductivity type; and
a logic cell, comprising:
at least one first transistor in a first active region over the first well region, and comprising a first gate electrode extending in a first direction;
at least one second transistor in a second active region over the second well region, wherein the second transistor and the first transistor share the first gate electrode;
a second gate electrode and a third gate electrode on opposite sides of the first transistor and extending in the first direction; and
a first isolation structure and a second isolation structure on opposite edges of the second active region and extending in the first direction,
wherein the first isolation structure is aligned with the second gate structure in the first direction, and the second isolation structure is aligned with the third gate structure in the first direction.

2. The semiconductor structure as claimed in claim 1, wherein the second and third gate electrodes are shorter than the first gate electrode in the first direction.

3. The semiconductor structure as claimed in claim 1, wherein the first and second isolation structures are shorter than the first gate electrode in the first direction.

4. The semiconductor structure as claimed in claim 1, further comprising:
a first power line over the first well region and extending in a second direction, wherein the second direction is perpendicular to the first direction;
a second power line over the second well region and extending in the second direction; and
at least one additional power line extending in the second direction and over the first active region,
wherein the first power line is electrically separated from the second power line;
wherein the second and third gate electrodes are electrically connected to the first power line through the additional power line.

5. The semiconductor structure as claimed in claim 4, wherein the first power line, the second power line and the additional power line are formed in the same metal layer.

6. The semiconductor structure as claimed in claim 4, wherein the first and second power lines are wider than the additional power line.

7. The semiconductor structure as claimed in claim 4, further comprising:
a plurality of signal lines extending in the second direction,
wherein the additional power line and the signal lines are formed in the same metal layer and arranged with a fixed pitch between the first and second power lines.

8. The semiconductor structure as claimed in claim 7, wherein the additional power line is separated from the first power line by one of the signal lines.

9. A semiconductor structure, comprising:
a semiconductor substance;
a logic cell, comprising:
at least one first transistor in a first active region over the semiconductor substrate, and comprising a first gate electrode extending in a first direction;
at least one second transistor in a second active region over the semiconductor substrate, wherein the second transistor and the first transistor share the first gate electrode;
a second gate electrode and a third gate electrode on opposite sides of the first transistor and extending in the first direction; and
a fourth gate electrode and a fifth gate electrode on opposite sides of the second transistor and extending in the first direction;
a first power line extending in a second direction, wherein the second direction is perpendicular to the first direction;
a second power line extending in the second direction, wherein the logic cell is surrounded by the first and second power lines, and the first power line is electrically separated from the second power line; and
a first additional power line extending in the second direction and over the first active region,
wherein the fourth gate structure is electrically separated from the second gate structure, and the fifth gate structure is electrically separated from the third gate structure,
wherein the second and third gate electrodes are electrically connected to the first power line through the first additional power line.

10. The semiconductor structure as claimed in claim 9, wherein the second, third, fourth and fifth gate electrodes are shorter than the first gate electrode in the first direction.

11. The semiconductor structure as claimed in claim 9, wherein the second, third, fourth and fifth gate electrodes and the first gate electrode have the same width in the second direction.

12. The semiconductor structure as claimed in claim 9, further comprising:
a second additional power line extending in the second direction and over the second active region;
wherein the fourth and fifth gate electrodes are electrically connected to the second power line through the second additional power line.

13. The semiconductor structure as claimed in claim 12, wherein the first power line, the second power line, the first additional power line and the second additional power line are formed in the same metal layer, and the first and second additional power lines are arranged between the first power line and the second power line.

14. The semiconductor structure as claimed in claim 12, wherein the first and second power lines are wider than the first and second additional power lines.

15. The semiconductor structure as claimed in claim 12, further comprising:
a plurality of signal lines extending in the second direction,
wherein the first and second additional power lines and the signal lines are formed in the same metal layer and arranged between the first power line and the second power line according to a fixed pitch.

16. The semiconductor structure as claimed in claim 15, wherein the first additional power line is separated from the first power line by one of the signal lines, and the second additional power line is separated from the second power line by another signal line.

17. A semiconductor structure, comprising:
a semiconductor substrate; and
a cell array, comprising:
a first logic cell, comprising:
at least one first transistor in a first active region over the semiconductor substrate, and comprising a first gate electrode extending in a first direction; and
at least one second transistor in a second active region over the semiconductor substrate, wherein the second transistor and the first transistor share the first gate electrode; and
a second logic cell, comprising:
at least one third transistor in the first active region, and comprising a second gate electrode extending in the first direction; and
at least one fourth transistor in a third active region over the semiconductor substrate, wherein the third transistor and the fourth transistor share the second gate electrode;
a third gate electrode, a fourth gate electrode and a fifth gate electrode extending in the first direction; and
a first isolation structure, a second isolation structure and a third isolation structure extending in the first direction,
wherein the third gate electrode and the fourth gate electrode are disposed on opposite sides of the first transistor, and the fourth gate electrode and fifth gate electrode are disposed on opposite sides of the third transistor,
wherein the first isolation structure and the second isolation structure are disposed on opposite edges of the second active region, and the second isolation structure and the third isolation structure are disposed on opposite edges of the third active region,
wherein the second active region is separated from the third active region by the second isolation structure.

18. The semiconductor structure as claimed in claim 17, further comprising:
a first power line extending in a second direction across the first and second logic cells, wherein the second direction is perpendicular to the first direction;
a second power line extending in the second direction across the first and second logic cells; and
at least one additional power line extending in the second direction across the first and second logic cells and formed over the first active region,
wherein the first power line is electrically separated from the second power line;
wherein the third, fourth and fifth gate electrodes are electrically connected to the first power line through the additional power line.

19. The semiconductor structure as claimed in claim 18, wherein the first power line, the second power line and the additional power line are formed in the same metal layer, and the first and second power lines are wider than the additional power line.

20. The semiconductor structure as claimed in claim 19, further comprising:
a plurality of signal lines extending in the second direction across the first and second logic cells,
wherein the additional power line and the signal lines are formed in the same metal layer and arranged between the first and second power lines according to a fixed pitch.
